(19) United States
(12) Patent Application Publication
(10) Pub. No.: US 2009/0273002 A1
(43) Pub. Date: Nov. 5, 2009

(54) LED Package Structure and Fabrication Method

(76) Inventors: Wen-Chih Chiou, Miaoli (TW); Chen-Hua Yu, Hsin-Chu (TW); Ding-Yuan Chen, Taichung (TW)

Correspondence Address: SLATER & MATSIL, L.L.P., 17950 PRESTON ROAD, SUITE 1000, DALLAS, TX, 75252, US

(21) Appl. No.: 12/235,193

(22) Filed: Sep. 22, 2008

Related U.S. Application Data
(60) Provisional application No. 61/050,529, filed on May 5, 2008.

(51) Int. Cl. H01L 33/00

(52) U.S. Cl. 257/99; 257/E33.058

(57) ABSTRACT

System and method for packaging an LED is presented. A preferred embodiment includes a plurality of thermal vias located through the packaging substrate to effectively transfer heat away from the LED, and are preferably formed along with conductive vias that extend through the packaging substrate. The thermal vias are preferably in the shape of circles or rectangular, and may either be solid or else may encircle and enclose a portion of the packaging substrate.

This application claims the benefit of U.S. Provisional Application No. 61/050,529, filed on May 5, 2008, entitled “LED Package Structure and Fabrication Method,” which application is hereby incorporated herein by reference.

### TECHNICAL FIELD

The present invention relates generally to a system and method for light-emitting diodes (LEDs) and, more particularly, to a system and method for packaging LEDs.

### BACKGROUND

Generally, the demand for LEDs, and especially high-brightness, high-power LEDs, has increased over the past years. However, high-brightness, high-power LEDs, while generating large amounts of light, also generate large amounts of heat which can cause thermal degradation of the characteristics of the LEDs and reduce the overall lifespan of the LEDs. Accordingly, this heat must be transferred away from the LED as quickly and efficiently as possible.

Recent techniques in the packaging of LEDs have led to the use of packages that contain a silicon substrate. This silicon substrate generally has good processability and relatively decent heat conductivity through the silicon substrate. These silicon substrate packages either use the silicon substrate itself to transfer the heat, or else have heat transfer devices, such as buried metallic regions, formed within the silicon substrate to enhance the heat transfer. Unfortunately, these devices have not been efficient enough to solve the thermal degradation problem of LEDs.

As such, what is needed is an improved device and method for transferring heat through an LED package and away from the LEDs contained within the package.

### SUMMARY OF THE INVENTION

These and other problems are generally solved or circumvented, and technical advantages are generally achieved, by preferred embodiments of the present invention which provide for an LED package.

In accordance with a preferred embodiment of the present invention, an LED package comprises a substrate with a first side and a second side. A first contact pad and a second contact pad are located on the first side of the substrate and a third contact pad and fourth contact pad are located on the second side of the substrate. The first contact pad is connected to the third contact pad through a first conductive via and the second contact pad is connected to the fourth contact pad through a second conductive via. An LED is electrically connected to both the first contact pad and the second contact pad, and one or more thermal vias are located in the substrate beneath the LED, the one or more thermal vias extending from the first side of the substrate to the second side of the substrate.

In accordance with another preferred embodiment of the present invention, a package comprises an LED with a first contact and a second contact. A substrate with first contact pad and a second contact pad is electrically connected to the first contact and the second contact, respectively. A first conductive via connects the first contact pad to a third contact pad and a second conductive via connects the second contact pad to a fourth contact pad, the third contact pad and the fourth contact pad being located on an opposite side of the substrate than the LED. One or more thermal vias extend through the substrate from the first contact pad.

In accordance with yet another preferred embodiment, a method for packaging an LED comprises providing a substrate with a first side and second side opposite the first side, and forming a first conductive via and a second conductive via extending through the substrate. One or more thermal vias are formed extending through the substrate. A first contact pad is formed on the first side of the substrate over the first conductive via and at least one of the one or more thermal vias, and a second contact pad is formed on the first side of the substrate over the second conductive via. An LED is attached to the first contact pad and the second contact pad.

An advantage of a preferred embodiment of the present invention is that the heat generated by the LED is more quickly and efficiently transported away from the LED and through the package. This leads to less heat degradation and a corresponding increase in the lifespan of the LED, while the use of relatively simple and inexpensive manufacturing technologies allow embodiments of the present invention to be easily implemented.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1-3 illustrate steps in the manufacturing of an LED package in accordance with an embodiment of the present invention;

FIGS. 4A-4E illustrate plan views of thermal vias in an LED package in accordance with an embodiment of the present invention;

FIGS. 5-8 illustrate further manufacturing steps in the manufacturing of an LED package in accordance with an embodiment of the present invention; and

FIG. 9 illustrates an LED package with three contacts on an opposite side of a substrate from the LED in accordance with an embodiment of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a packaging structure for LEDs. The invention may also be applied, however, to packaging structures for different components.

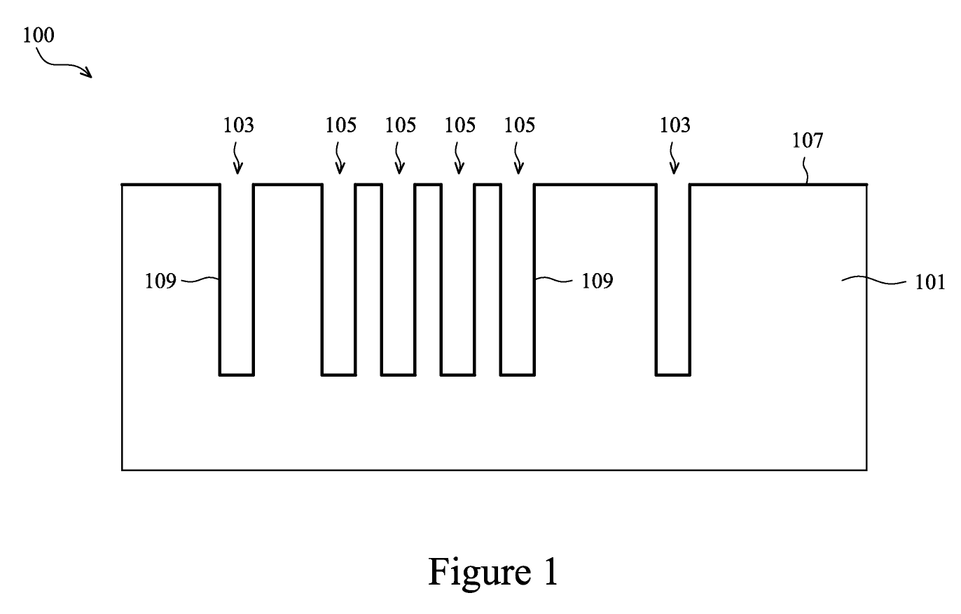

With reference now to FIG. 1, there is shown a cross-sectional view of a package 100 with a substrate 101 with contact openings 103 and thermal openings 105 formed therein. The substrate 101 may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The contact openings 103 and thermal openings 105 are preferably formed by applying and developing a suitable photoresist (not shown) over a first side 107 of the substrate 101, and then etching through at least a portion of the substrate 101. Preferably, the contact openings 103 and thermal openings 105 are formed so as to extend into the substrate 101 at least further than the eventual desired thickness of the substrate 101. Accordingly, while the depth of the contact openings 103 and thermal openings 105 from the first side 107 of the substrate 101 is dependent upon the overall design of the package 100, the depth is preferably between about 150 μm and about 750 μm, with a preferred depth of about 300 μm.

Preferably, after the contact openings 103 and thermal openings 105 have been formed, the sidewalls of the contact openings 103 and thermal openings 105 are lined with an isolation layer 109 in order to separate the contact openings 103 and the thermal openings 105 from the surrounding substrate 101. The isolation layer 109 may comprise a dielectric layer of a material such as tetraethylorthosilicate (TEOS) or silicon nitride, formed through a process such as plasma enhanced chemical vapor deposition (PECVD), although other suitable materials and processes may alternatively be used. The isolation layer 109 may also comprise a barrier layer of material such as titanium nitride, tantalum nitride, or titanium, made through a process such as CVD or PECVD, although other suitable materials and processes may alternatively be used.

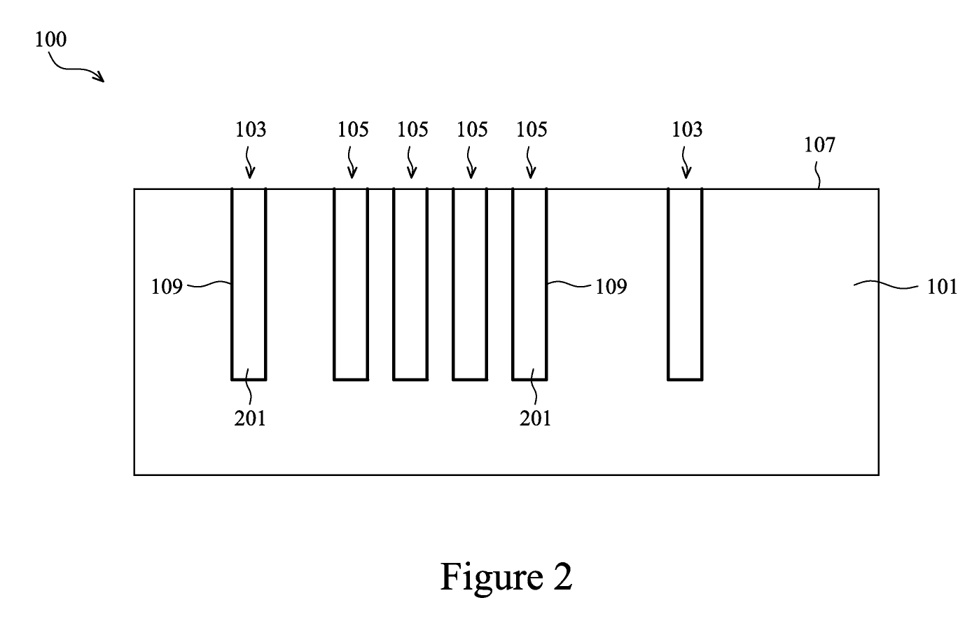

The isolation layer 109 is preferably formed so as to conformally cover the first side 107 of the substrate 101, the sidewalls of the contact openings 103 and the thermal openings 105, and the bottom of the contact openings 103 and the thermal openings 105. By forming the isolation layer 109 along the first side 107 of the substrate 101 as well as within the contact openings 103 and the thermal openings 105, the substrate 101 is protected from the subsequent deposition of a material such as copper (described below with respect to FIG. 2). Alternatively, the isolation layer 109 may be anisotropically etched after formation such that the isolation layer 109 is removed from the horizontal surfaces of the surface, and leaving the isolation layer 109 only along the sidewalls of the contact openings 103 and the thermal openings 105.

FIG. 2 illustrates the filling of the contact openings 103 and thermal openings 105 with a conductive material 201. The conductive material 201 preferably comprises copper, although other conductive materials, such as tungsten, may alternatively be used. Preferably, a seed layer (not shown) is formed over the isolation layer 103, and an electrodeposition process is utilized to fill and overfill the contact openings 103 and thermal openings 105 with conductive material 201, although other suitable methods, such as electroless deposition, plating, or CVD, may also be used. After overfilling the contact openings 103 and thermal openings 105, excess conductive material 201 and portions of the isolation layer 109 located outside of the contact openings 103 and thermal openings 105 are preferably removed using a process such as chemical mechanical polishing (CMP), etching, combinations of these, or the like, to isolate the remaining conductive material 201 in the contact openings 103 and thermal openings 105. Alternatively, the removal process may remove the excess conductive material 201 without substantially removing the isolation layer 109, thereby leaving a portion of the isolation layer 109 on the first side 107 of the substrate 101.

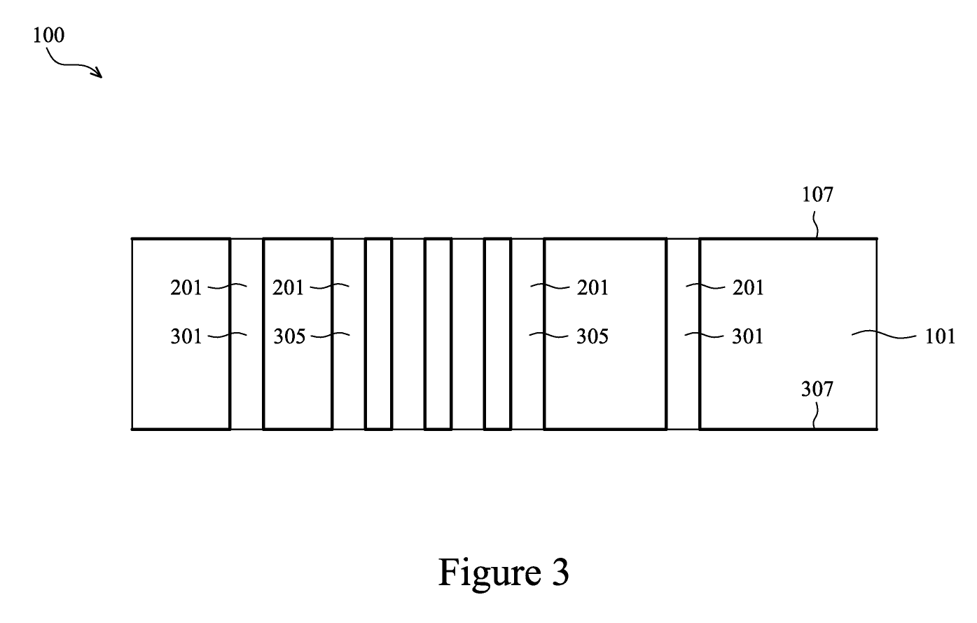

FIG. 3 illustrates the formation of contact through silicon vias (TSVs) 301 and thermal vias 305 from the contact openings 103 and the thermal openings 105, respectively. To form the contact TSVs 301 and thermal vias 305, portions of a second side 307 of the substrate 101 are removed to expose the conductive material 201 located within the contact openings 103 and the thermal openings 105. The removal is preferably performed with a grinding process such as a chemical mechanical polish, although other suitable processes, such as etching, may alternatively be used.

As one of skill in the art will recognize, the process presented above to form the contact TSVs 301 and the thermal vias 305, including the formation of the contact openings 103 and thermal openings 105, deposition of a conductive material 201, and subsequent thinning of the second side 307 of the substrate 101, is merely one method to form the contact TSVs 301 and the thermal vias 305. In another method, the contact TSVs 301 and the thermal vias 305 may be formed by etching vias partially through the substrate 101 and depositing a dielectric material in the vias. In this embodiment, the dielectric layer within the vias is removed after the second side 307 of the substrate 101 is thinned, and the conductive material 201 is re-deposited within the via. This method, and any other suitable method for forming the contact TSVs 301 and the thermal vias 305, may alternatively be used and are fully intended to be included within the scope of the present invention.

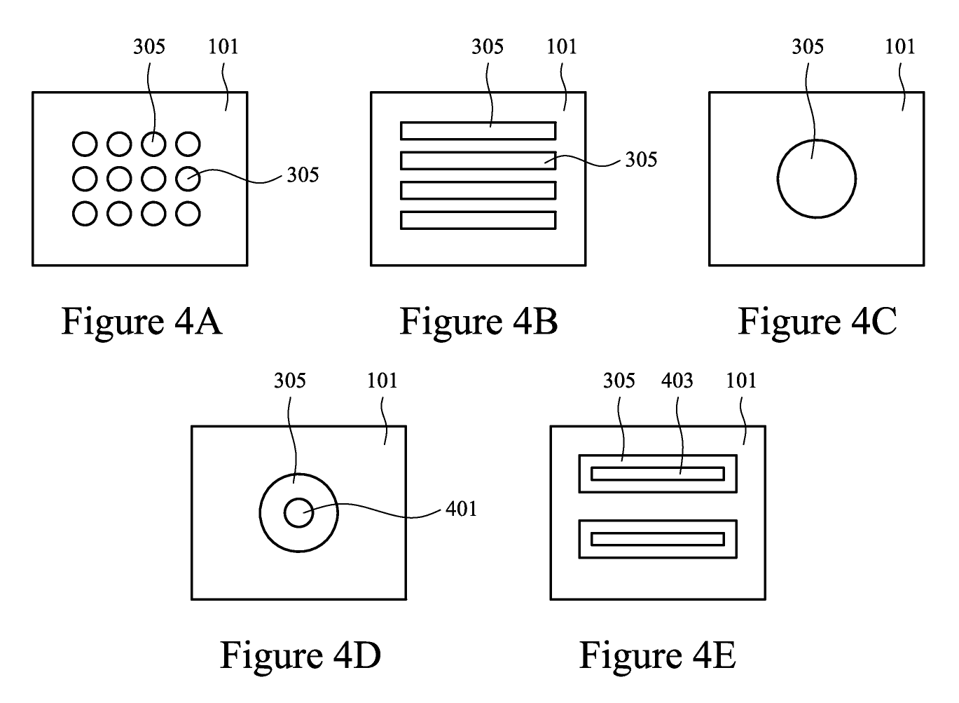

FIGS. 4A-4E illustrate plan views of various embodiments of the present invention regarding the shape and layout of the thermal vias 305 on the substrate 101. Generally, there could be any desired number of thermal vias 305, with a preferred number being between 1 and 25, and an even more preferred number of 9. Additionally, the thermal vias 305 preferably are either circular or rectangular in shape, although other shapes may alternatively be used.

FIG. 4A illustrates a preferred layout of thermal vias 305 arranged in a grid pattern. These thermal vias 305 are circular and have a preferred diameter of between about 50 μm and about 300 μm, with a preferred diameter of about 80 μm. The grid pattern preferably has a pitch between thermal vias 305 of about 100 μm and about 500 μm, with a preferred pitch of about 160 μm. However, the grid pattern and number of thermal vias 305 described are meant to be merely illustrative, and are not meant to limit the present invention, as other patterns and number of thermal vias 305, such as a staggered pattern of vias, are also intended to be included within the scope of the present invention.

FIG. 4B illustrates another embodiment in which the thermal vias 305 are rectangular lines arranged next to each other such that the thermal vias 305 do not overlap. In this embodiment the thermal vias 305 preferably have a length of between about 100 μm and about 1,200 μm, with a preferred length of about 600 μm, and preferably have a width of between about 50 μm and about 300 μm, with a preferred width of about 80 μm. Additionally, the thermal vias 305 are preferably arranged so as to be spaced apart from each other between about 50 μm and about 500 μm, with a preferred spacing of about 80 μm. Alternatively, the thermal vias 305 may be arranged so that the rectangular lines are offset from each other.

FIG. 4C illustrates yet another embodiment in which a single thermal via 305 is utilized. In this embodiment the thermal via 305 is preferably circular, similar to the embodiment described above with reference to FIG. 4A. In this embodiment, however, the single, circular thermal via 305 is preferably formed to have a larger diameter than the thermal vias 305 formed in the embodiment of FIG. 4A, and preferably has a diameter of between about 100 μm and about 800 μm, with a preferred diameter of about 300 μm.

FIG. 4D illustrates a variation of the single, circular thermal via 305 depicted in FIG. 4C. In this embodiment the thermal via 305 is in the shape of a ring containing a plug 401 of the substrate 101 encircled by the thermal via 305. The plug 401 preferably has a diameter of between about 50 μm and about 500 μm, with a preferred diameter of about 120 μm. This embodiment has the additional benefit of being able to relieve some of the stresses between the thermal via 305 and the surrounding substrate 101.

FIG. 4E illustrates yet another embodiment of the present invention in which the thermal vias 305 are preferably rectangular in shape and additionally have a slot 403 of the substrate 101 running along a center of the thermal vias 305. The slots 403 preferably have a width (in the same direction as the width of the thermal vias 305) of between about 50 μm and about 300 μm, with a preferred width of about 80 μm and a length (in the same direction as the length of the thermal vias 305) of between about 100 μm and about 1,000 μm, with a preferred length of about 500 μm. The thermal vias 305 in this embodiment are preferably aligned with each other, but may alternatively be offset from each other. This embodiment, similar to the embodiment described in relation to FIG. 4D, also is able to relieve some of the stresses between the thermal via 305 and the surrounding substrate 101.

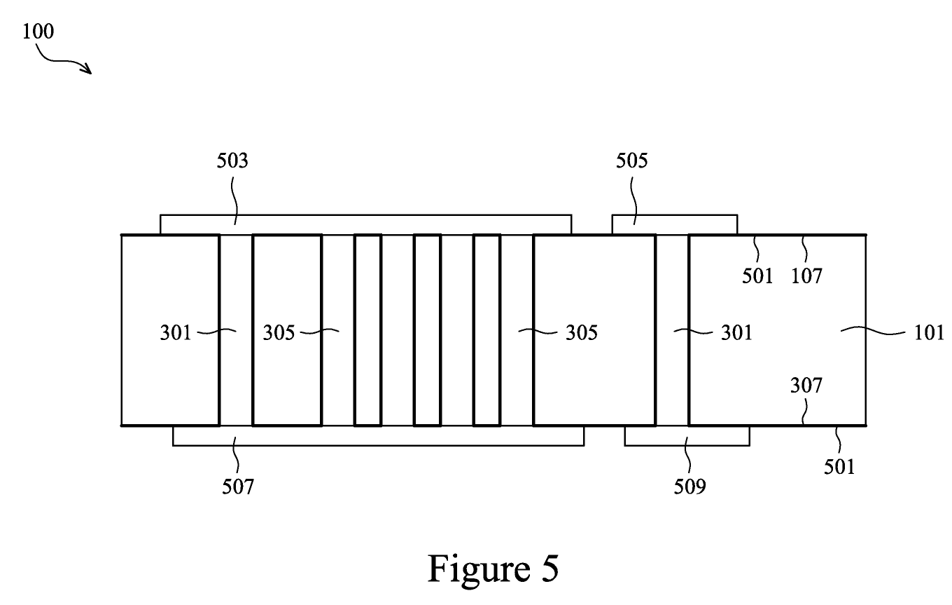

FIG. 5 illustrates the formation of a passivation layer 501 and electrodes over the exposed first side 107 and the second side 307 of the substrate 101. Alternatively, in an embodiment in which the isolation layer 109 remains over the first side 107 of the substrate 101, the passivation layer 501 may be formed only over the second side 307 of the substrate as the first side 107 of the substrate 101 is already protected. The passivation layer 501 preferably comprises silicon dioxide formed by exposing the substrate 101 to an oxidizing ambient such as oxygen (O₂) or water (H₂O), although other processes such as CVD followed by a photolithographic etch may alternatively be used. The passivation layer 501 preferably protects the surfaces of the substrate 101 while leaving the conductive material 201 in the contact TSVs 301 and the thermal vias 305 exposed.

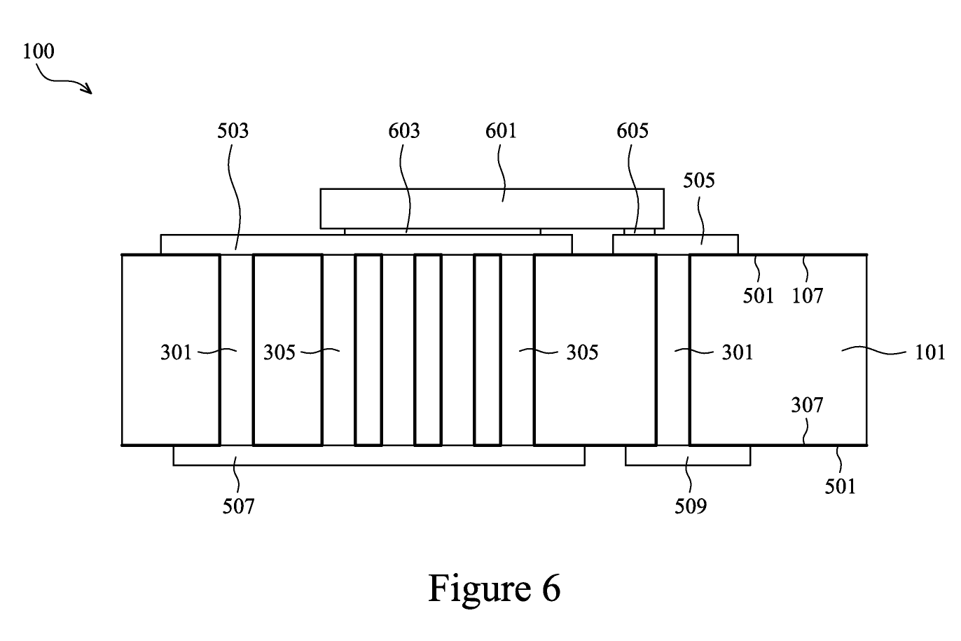

A first upper electrode 503 is preferably formed over the passivation layer 501 on the first side 107 of the substrate 101. The first upper electrode 503 is formed in electrical connection with at least one of the contact TSVs 301 and at least one of the thermal vias 305. The first upper electrode 503 preferably provides electrical connection between one or more of the contact TSVs 301 and an LED 601 (described below with reference to FIG. 6).

A second upper electrode 505 is preferably formed over the passivation layer 501 on the first side 107 of the substrate 101, and in electrical contact with at least one contact TSV 301 not connected to the first upper electrode 503. The second upper electrode 505 preferably provides a second contact for the LED 601. Optionally, the second upper electrode 505 may also be in contact with one or more thermal vias 305, although separate thermal vias 305 than the first upper electrode 503.

A first lower electrode 507 is preferably formed over the passivation layer 501 on the second side 307 of the substrate 101. The first lower electrode 507 is preferably connected to at least one of the same contact TSVs 301 as the first upper electrode 503, and may also be in contact with one or more of the thermal vias 305. The first lower electrode 507, in conjunction with the contact TSVs 301 and the first upper electrode 503, provides an electrical pathway between the first side 107 of the substrate 101 and the second side 307 of the substrate 101, while keeping the attached thermal vias 305 at the same electrical potential as the contact TSVs 301. In an embodiment in which the electrical potential is a ground, preferably having the thermal vias 305 and the contact TSVs 301 at the same electrical potential will additionally provide a better ground quality than otherwise.

A second lower electrode 509 is preferably formed over the passivation layer 501 on the second side 307 of the substrate 101 and separated from the first lower electrode 507. The second lower electrode 509 is preferably connected to at least one of the same contact TSVs 301 as the second upper electrode 505, and may also be connected to one or more of the thermal vias 305 that are not connected to the first upper electrode 503.

The first upper electrode 503, second upper electrode 505, first lower electrode 507, and second lower electrode 509 are preferably formed of two layers (not shown individually): a first conductive layer and an Electroless Nickel Gold (ENIG) layer. The first conductive layer preferably comprises aluminum, and is preferably formed through a sputter deposition process. However, other materials, such as nickel or copper, and other formation processes, such as electroplating or electroless plating, may alternatively be used. The first conductive layer is preferably formed with a thickness of between about 1 μm and about 3 μm, with a preferred thickness of about 2 μm.

The formation of the first conductive layer is preferably followed by an Electroless Nickel Gold (ENIG) process to form an ENIG layer. The ENIG process provides for a flat, uniform metal surface finish for the formation of contacts from the contact TSVs 301 and the thermal vias 305. The ENIG process preferably comprises cleaning the first conductive layer, immersing the substrate 101 in a zincate activation solution, electrolessly plating nickel onto the first conductive layer, and electrolessly plating gold onto the nickel. The ENIG layer is preferably formed to a thickness of between about 2 μm and about 8 μm, with a preferred thickness of about 3 μm. Once formed, the first conductive layer and the ENIG layer are preferably patterned by a suitable photolithographic process and unwanted material is removed through a suitable etching process to separate the first conductive layer and the ENIG layer into the first upper electrode 503, second upper electrode 505, first lower electrode 507, and second lower electrode 509.

While the first upper electrode 503, second upper electrode 505, first lower electrode 507, and second lower electrode 509 are described as being formed of the same material, one of ordinary skill in the art will realize that this is merely illustrative and that different materials and processes may be used for each electrode. Other suitable materials and processes, such as patterning the first conductive layer prior to the ENIG process, that may be used to form the first upper electrode 503, second upper electrode 505, first lower electrode 507, and second lower electrode 509 may alternatively be used, and are fully intended to be included within the scope of the present invention.

In an embodiment in which the LED has horizontal contacts with FIG. 6 illustrates the placement of an LED 601 in electrical contact with the first upper electrode 503 and the second upper electrode 505. The LED 601 preferably comprises at least a first contact layer comprising an n-type group III-V compound, a second contact layer comprising a p-type group III-V compound, and an active layer with multiple quantum wells between the first contact layer and the second contact layer. Optionally, the LED 601 may comprise additional layers such as buffer layers and Bragg reflective layers to enhance operation. These layers are oriented in relation to each other such that, when current is passed through the diode formed by the first contact layer and the second contact layer, the active layer will emit electromagnetic radiation such as visible, ultraviolet, infrared light, or the like.

In an embodiment in which the LED 601 is a horizontal LED, the LED 601 is preferably flip-chip bonded to the first upper electrode 503 and the second upper electrode 505. In this bonding the LED 601 preferably has a first LED contact 603 (preferably electrically connected to the p-type second contact layer) and a second LED contact 605 (preferably electrically connected to the n-type first contact layer) formed either on or within the same surface of the LED 601. The LED is then “flipped” so that the first LED contact 603 and the second LED contact 605 are in contact with the first upper electrode 503 and the second upper electrode 505, respectively. The open space between the LED and the first upper electrode 503 and the second upper electrode 505 is preferably filled with an epoxy resin (not shown) to bond the LED 601 to the package 100.

As one of ordinary skill in the art will realize, the above described method of flip-chip bonding the LED 601 to the package 100 is not the sole bonding method available to attach the LED 601 to the package 100. Alternatively, solder may be used to form the connections between the first upper electrode, the second upper electrode, and the LED; a lead wire may be used to connect the LED 601 to the first upper electrode 503 and the second upper electrode 505; or, in an embodiment in which the LED 601 is a vertical LED where the first LED contact 603 and the second LED contact 604 are on opposite sides of the LED 601, a combination of flip-chip and lead wire connections may be used. Any suitable bonding method may be used to attach the LED 601 to the package 100, and all suitable methods are fully intended to be included within the scope of the present invention.

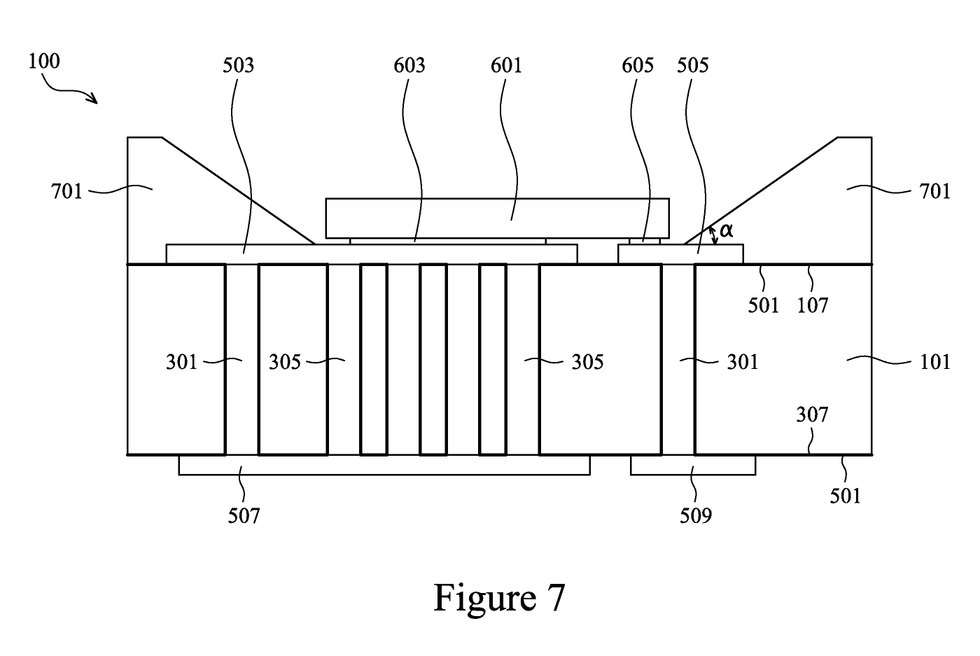

FIG. 7 illustrates the formation of reflective components 701 to direct light emitted from the LED 601 upwards, thereby increasing the efficiency of the LED package 100. The reflective components 701 preferably comprise a material such as silicon or ceramic, and are preferably sloped at an angle α so as to direct incident light upwards. The angle α is preferably between about 200 and about 700, with a preferred angle of about 55°.

The reflective components 701 are preferably attached to the package 100 over portions of the first upper electrode 503 and the second upper electrode 505, while not contacting the LED 601. Additionally, to enhance the reflectivity of the reflective components 701, the reflective components are preferably coated with a material having a high reflectivity, such as silver or nickel.

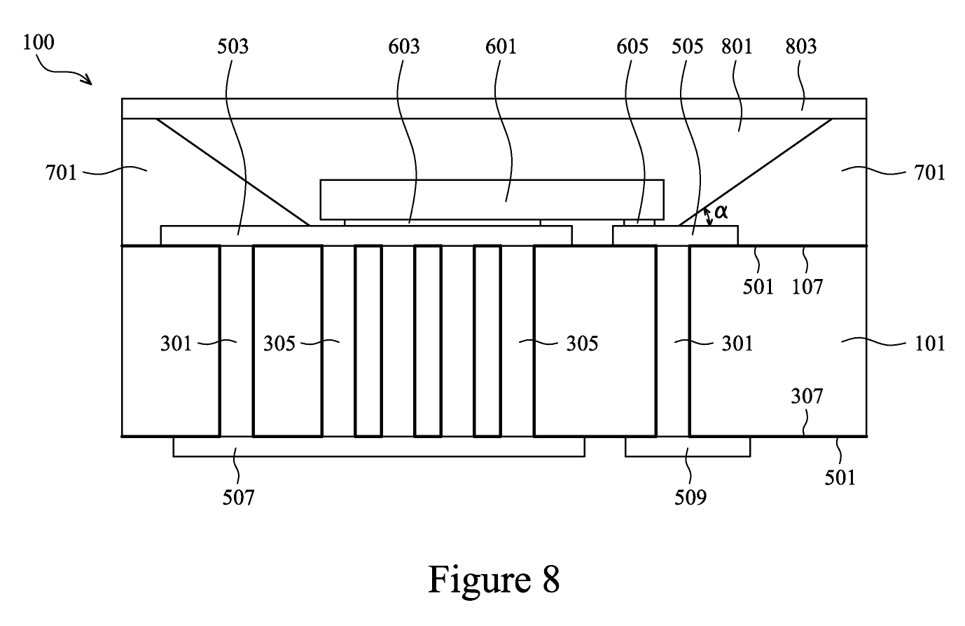

FIG. 8 illustrates an encapsulation and covering of the LED 601. The encapsulant 801 preferably comprises a material that is transparent to LED radiation (e.g., visible light) such as an epoxy, a glass filled epoxy, or a polymer material such as silicone. Optionally, the encapsulant 801 may comprise a phosphor material that can modify the wavelength of the light emitted by the LED 601. The encapsulant 801 preferably covers the LED 601 and fills the cavity formed by the reflective components 701 in order to protect the LED 601 from environmental hazards. The encapsulant 801 is preferably deposited in a liquid state and then cured in order to harden the encapsulant 801.

Once the encapsulant 801 has been formed, a cover 803 is preferably placed over the encapsulated LED 601. The cover 803 preferably comprises a lens to improve the light output of the LED and further protect the LED 601 from environmental hazards. The cover 803 preferably comprises a material that is transparent to LED radiation (e.g., visible light) and able to protect the LED 601, such as polycarbonate or a similar hard plastic, and is preferably aligned with and bonded to the reflective components 701 with a sealant such as epoxy.

By forming the thermal vias 305 through the substrate 101, beneath the LED 601, and extending from either the first contact pad 503 or the second contact pad 505, the efficiency of the heat transfer from the LED 601 to the exterior of the package 100 can be greatly increased. This directly leads to an increase in the transfer of generated heat and can reduce or eliminate the thermal degradation and its corresponding reduction in the lifespan of the LED 601.

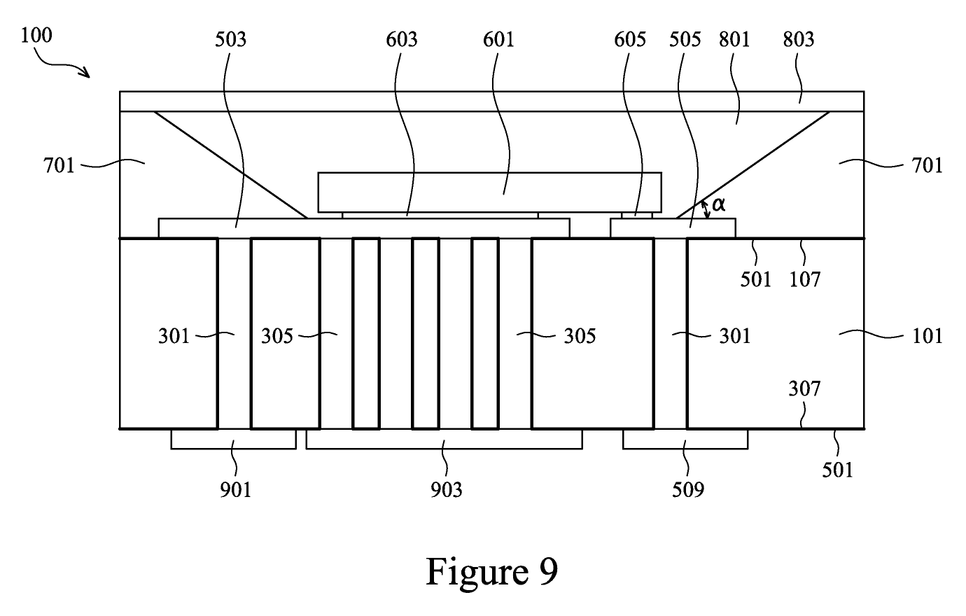

FIG. 9 illustrates another embodiment of the present invention wherein the single first lower electrode 507 (illustrated in FIGS. 4-8) is instead formed as two separate electrodes: a third lower electrode 901 and a fourth lower electrode 903. While the third lower electrode 901 and the fourth lower electrode 903 are preferably formed similar to the first lower electrode (whose formation is described above with reference to FIG. 4), the first conductive layer and the ENIG layer are patterned so that the third lower electrode 901 is electrically connected to the contact TSVs 301 while the fourth lower electrode 903 is electrically connected to the thermal vias 305. By separating the third lower electrode 901 and the fourth lower electrode 903 as described, noise that may originate from the heat sink may additionally be reduced or eliminated.

Although the present invention and its advantages have been described in detail, it should be understood that various changes, substitutions and alterations can be made herein without departing from the spirit and scope of the invention as defined by the appended claims. For example, it will be readily understood that, while a preferred embodiment has the contact TSVs and thermal vias being formed from the same material, different materials may also be used. As another example, it will be readily understood by those skilled in the art that processes used to form the various structures may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An LED package comprising:
a substrate with a first side and a second side;
a first contact pad and a second contact pad located on the first side of the substrate, and a third contact pad and a fourth contact pad located on the second side of the substrate, the first contact pad connected to the third contact pad through a first conductive via and the second contact pad connected to the fourth contact pad through a second conductive via;
an LED electrically connected to both the first contact pad and the second contact pad; and
one or more thermal vias located in the substrate beneath the LED, the one or more thermal vias extending from the first side of the substrate to the second side of the substrate.

2. The LED package of claim 1, wherein the one or more thermal vias comprise a plurality of thermal vias arranged in a grid array.

3. The LED package of claim 1, wherein the one or more thermal vias is rectangular in shape.

4. The LED package of claim 1, wherein the one or more thermal vias is a single cylindrical via.

5. The LED package of claim 1, wherein the one or more thermal vias is in the shape of a ring.

6. The LED package of claim 1, wherein the one or more thermal vias comprises a rectangular shape that encloses a portion of the substrate.

7. The LED package of claim 1, wherein the one or more thermal vias extend between the first contact pad and the third contact pad.

8. The LED package of claim 1, further comprising a fifth contact pad on the second side of the substrate, the one or more thermal vias extending between the first contact pad and the fifth contact pad.

9. A package comprising:
an LED with a first contact and a second contact;
a substrate with a first contact pad electrically connected to the first contact and a second contact pad electrically connected to the second contact;
a first conductive via connecting the first contact pad to a third contact pad and a second conductive via connecting the second contact pad to a fourth contact pad, the third contact pad and the fourth contact pad on an opposite side of the substrate than the LED; and
one or more thermal vias extending through the substrate from the first contact pad.

10. The package of claim 9, wherein the one or more thermal vias extend from the first contact pad to the third contact pad.

11. The package of claim 9, further comprising a fifth contact pad on an opposite side of the substrate than the LED, wherein the one or more thermal vias extend from the first contact pad to the fifth contact pad.

12. The package of claim 9, wherein the one or more thermal vias are circular and are arranged in a grid pattern.

13. The package of claim 9, wherein the one or more thermal vias comprises lines.

14. The package of claim 9, wherein the one or more thermal vias each comprise an outer portion surrounding a portion of the substrate.

15. A light-generating device comprising:
a substrate with a first side and a second side opposite the first side;
a first conductive via and a second conductive via, the first conductive via and the second conductive via extending through the substrate;
one or more thermal vias extending through the substrate;
a first contact pad on the first side of the substrate over the first conductive via and at least one of the one or more thermal vias;
a second contact pad on the first side of the substrate over at least the second conductive via; and
an LED in electrical contact with the first contact pad and the second contact pad.

16. The light-generating device of claim 15, further comprising a third contact pad on the second side of the substrate, wherein both the first conductive via and the one or more thermal vias are electrically connected to the third contact pad.

17. The light-generating device of claim 15, further comprising:
a third contact pad on the second side of the substrate, wherein the at least one thermal via is electrically connected to the third contact pad;
a fourth contact pad on the second side of the substrate, wherein the first conductive via is electrically connected to the fourth contact pad; and
a fifth contact pad on the second side of the substrate, wherein the second conductive via is electrically connected to the fifth contact pad.

18. The light-generating device of claim 15, wherein the one or more thermal vias are circular.

19. The light-generating device of claim 15, wherein the one or more thermal vias are rectangular in shape.

20. The light-generating device of claim 15, wherein the one or more thermal vias each surround a portion of the substrate.
